(19) United States
(12) Patent Application Publication
(10) Pub. No.: US 2026/0324165 A1
(43) Pub. Date: Oct. 15, 2026

(54) LIGHT-EMITTING DEVICE AND CHARGED PARTICLE BEAM GENERATOR

(71) Applicant: KABUSHIKI KAISHA TOSHIBA, Kawasaki-shi (JP)

(72) Inventors: Akira FUJIMOTO, Kawasaki Kanagawa (JP); Shigeya KIMURA, Yokohama Kanagawa (JP); Hisao MIYAZAKI, Yokohama Kanagawa (JP); Yuma YAMAGUCHI, Kawasaki Kanagawa (JP)

(73) Assignee: KABUSHIKI KAISHA TOSHIBA, Kawasaki-shi (JP)

(21) Appl. No.: 19/551,732

(22) Filed: Feb. 27, 2026

(30) Foreign Application Priority Data
Mar. 4, 2025 (JP) 2025-033781

(51) Int. Cl. H10H 29/85; H10H 29/24; H10H 29/851; H10H 29/855

(52) U.S. Cl. CPC H10H 29/8508; H10H 29/24; H10H 29/851; H10H 29/8552

(57) ABSTRACT

A light-emitting device includes a light-emitting element array including a wiring substrate and a plurality of light-emitting elements mounted on the wiring substrate; and a hole member including a substrate and a plurality of through-holes formed in the substrate, the substrate including a first surface facing the light-emitting element array and a second surface located on a side opposite to the first surface. The plurality of through-holes respectively face light-emitting surfaces of the plurality of light-emitting elements.

### CROSS-REFERENCE TO RELATED APPLICATION

This application is based upon and claims the benefit of priority from Japanese Patent Application No. 2025-033781, filed on Mar. 4, 2025; the entire contents of which are incorporated herein by reference.

### FIELD

Embodiments of the invention relate to a light-emitting device and a charged particle beam generator.

### BACKGROUND

In a micro LED (Light-Emitting Diode) array, unintended light leakage (crosstalk) between adjacent LEDs is a concern.

### BRIEF DESCRIPTION OF THE DRAWINGS

FIG. 1 is a schematic plan view of a light-emitting device according to a first embodiment;

FIG. 2 is a cross-sectional view taken along line A-A in FIG. 1;

FIG. 3 is a schematic cross-sectional view showing a modification of the light-emitting device according to the first embodiment;

FIG. 4 is a schematic cross-sectional view of an electron beam generator according to a second embodiment;

FIG. 5 is a schematic cross-sectional view showing a first modification of the electron beam generator according to the second embodiment;

FIG. 6 is a schematic cross-sectional view showing a second modification of the electron beam generator according to the second embodiment;

FIG. 7 is a schematic cross-sectional view of an electron beam generator according to a third embodiment; and

FIG. 8 is a schematic cross-sectional view of a light-emitting device according to a fourth embodiment.

### DETAILED DESCRIPTION

According to embodiments of the invention, a light-emitting device includes: a light-emitting element array including a wiring substrate and a plurality of light-emitting elements mounted on the wiring substrate; and a hole member including a substrate and a plurality of through-holes formed in the substrate, the substrate including a first surface facing the light-emitting element array and a second surface located on a side opposite to the first surface, the plurality of through-holes respectively facing light-emitting surfaces of the plurality of light-emitting elements.

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing.

The same or similar elements are denoted by the same reference numerals.

### First Embodiment

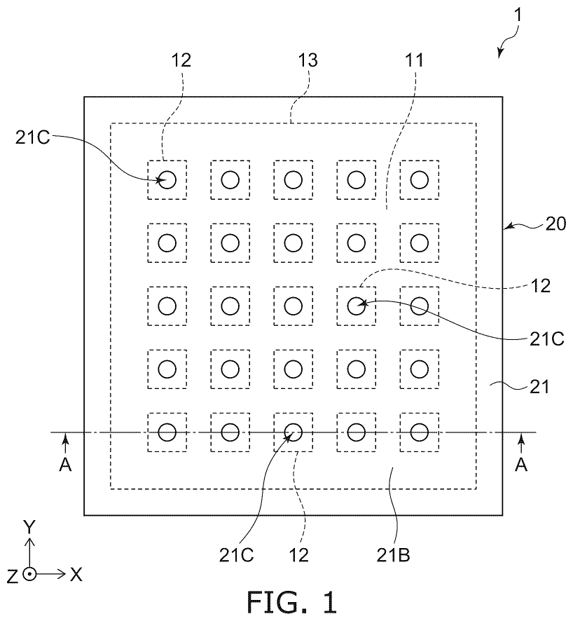

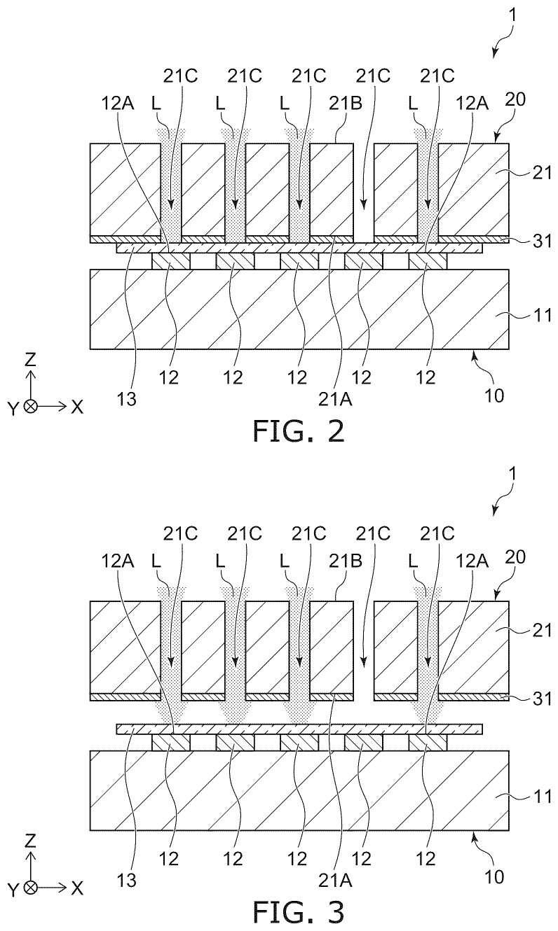

With reference to FIG. 1 and FIG. 2, a light-emitting device according to a first embodiment will be described.

A light-emitting device 1 according to the first embodiment includes a light-emitting element array 10 and a hole member 20. In each drawing, a direction from the light-emitting element array 10 toward the hole member 20 is defined a first direction Z. Two directions orthogonal to each other in a plane orthogonal to the first direction Z are defined as a second direction X and a third direction Y.

The light-emitting element array 10 includes a wiring substrate 11 and a plurality of light-emitting elements 12 mounted on the wiring substrate 11. The plurality of light-emitting elements 12 are mounted on the wiring substrate 11 so as to be arranged side by side in the second direction X and the third direction Y as shown in FIG. 1. The number and arrangement of the plurality of light-emitting elements 12 shown in FIG. 1 are examples, and the number and arrangement of the plurality of light-emitting elements 12 are not limited to those shown in FIG. 1.

The light-emitting element 12 is, for example, an LED and emits ultraviolet light. The peak wavelength of the light emitted by the light-emitting element 12 is, for example, 300 nm or less. The wiring substrate 11 includes a wiring portion at least on the upper surface, and each light-emitting element 12 is electrically connected to the wiring portion of the wiring substrate 11.

The light-emitting element array 10 further includes an element substrate 13. The plurality of light-emitting elements 12 are located between the wiring substrate 11 and the element substrate 13 in the first direction Z. The light-emitting element 12 includes, for example, a semiconductor portion obtained by separating a semiconductor layer (for example, a nitride semiconductor layer) grown on the element substrate 13 into a plurality of portions on the element substrate 13. The light-emitting element 12 further includes an electrode connected to the wiring portion of the wiring substrate 11. The element substrate 13 is transmissive to the light emitted by the light-emitting element 12 and is, for example, a sapphire substrate. The light-emitting element 12 includes a surface that is in contact with the element substrate 13 and that serves as a main light-emitting surface 12A. The element substrate 13 may be omitted.

The hole member 20 includes a substrate 21. The substrate 21 includes a first surface 21A facing the light-emitting element array 10 in the first direction Z, and a second surface 21B located on the side opposite to the first surface 21A in the first direction Z. The substrate 21 is, for example, a silicon substrate. The thickness of the substrate 21 is, for example, not less than 10 μm and not more than 1000 μm.

The hole member 20 further includes a plurality of through-holes 21C formed in the substrate 21. The through-hole 21C extends through the substrate 21 in the first direction Z and has an opening on each of the first surface 21A side and the second surface 21B side. The plurality of through-holes 21C extend through the substrate 21 from the second surface 21B in the first direction Z and reach the element substrate 13. The plurality of through-holes 21C are respectively located on the light-emitting surfaces 12A of the plurality of light-emitting elements 12. The plurality of through-holes 21C respectively face the light-emitting surfaces 12A of the plurality of light-emitting elements 12 in the first direction Z.

The plurality of light-emitting elements 12 can be individually controlled to emit or not emit light. In the drawings, the light emitted by the light-emitting element 12 is schematically indicated by hatching. For example, in FIG. 2, the second light-emitting element 12 from the right is not emitting light, and the other light-emitting elements 12 are emitting light. Light L emitted by the light-emitting element 12 enters the through-hole 21C from the light-emitting surface 12A through the element substrate 13. The light L entering the through-hole 21C is guided in the through-hole 21C and exits from the second surface 21B side to the outside of the substrate 21.

The distance (pitch) between the plurality of light-emitting elements 12 is, for example, 100 μm or less. In the plurality of light-emitting elements 12 arranged side by side at such a fine pitch, unintended light leakage (crosstalk) between the light-emitting elements 12 is a concern. In particular, in a case where the element substrate 13 is on the light-emitting surfaces 12A of the plurality of light-emitting elements 12, crosstalk between the adjacent light-emitting elements 12 caused by light guided in the element substrate 13 is likely to occur. For example, in a case where the light-emitting element array 10 and a photoelectric conversion layer described below are combined to generate a multi-electron beam, optical crosstalk in the light-emitting element array 10 causes an unintended position to be irradiated with the electron beam.

According to this embodiment, since the light exiting from the light-emitting surface 12A of each light-emitting element 12 is made to enter the through-hole 21C formed in the substrate 21, it is possible to provide the light-emitting device 1 in which optical crosstalk between the adjacent light-emitting elements 12 is reduced.

The reflectance of the inner wall of the through-hole 21C with respect to the light emitted by the light-emitting element 12 is preferably 50% or more. Accordingly, it is possible to prevent the light entering the through-hole 21C located on the light-emitting element 12 that is in a light-emitting state from being guided in the substrate 21 and leaking into the through-hole 21C located on the light-emitting element 12 that is in a non-light-emitting state. In this embodiment, the material of the substrate 21, which is silicon, has a reflectance of 70% or more with respect to the ultraviolet light emitted by the light-emitting element 12.

Further, aluminum having a high reflectance with respect to the ultraviolet light emitted by the light-emitting element 12 may be formed on the inner wall of the through-hole 21C. In a case where the light emitted by the light-emitting element 12 is in the visible range, silver may be formed on the inner wall of the through-hole 21C.

In this embodiment, the light-emitting device 1 further includes a first light absorbing layer 31 provided on the first surface 21A of the substrate 21. The first light absorbing layer 31 is absorptive of the light emitted by the light-emitting element 12. The first light absorbing layer 31 does not block the opening of the through-hole 21C on the first surface 21A side. In this embodiment, the first light absorbing layer 31 is in contact with the element substrate 13.

With the first light absorbing layer 31, it is possible to reduce crosstalk of the light exiting from the light-emitting surface 12A of the light-emitting element 12 before the light enters the through-hole 21C.

The reflectance of the first light absorbing layer 31 is preferably 10% or less, and the coefficient of absorption of the first light absorbing layer 31 is preferably 10 μm⁻¹ or more. The first light absorbing layer 31 can include, for example, at least one selected from the group consisting of an organic material, graphene, carbon nanotubes, and amorphous carbon.

As shown in FIG. 3, the hole member 20 may be apart from the light-emitting element array 10 in the first direction Z. In the example shown in FIG. 3, the first light absorbing layer 31 is apart from the element substrate 13 in the first direction Z. Even in this case, since the first light absorbing layer 31 is provided on the first surface 21A of the substrate 21, it is possible to reduce crosstalk of the light exiting from the light-emitting surface 12A of the light-emitting element 12 before the light enters the through-hole 21C. To reduce optical crosstalk between the adjacent light-emitting elements 12, the separation distance between the hole member 20 and the light-emitting element array 10 in the first direction Z is preferably 50 μm or less.

### Second Embodiment

A charged particle beam generator according to a second embodiment will be described. In this specification, an electron beam generator will be described as an example of the charged particle beam generator.

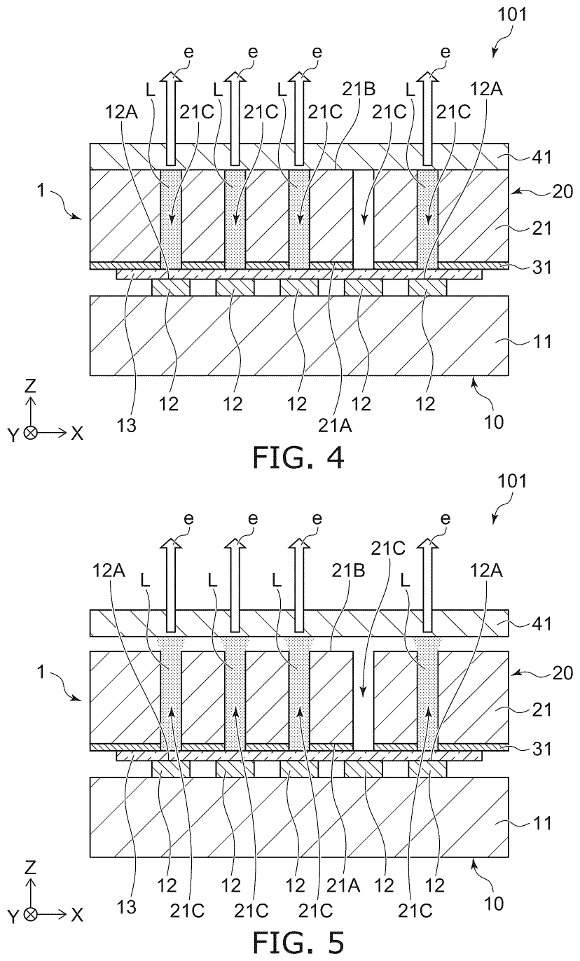

FIG. 4 is a schematic cross-sectional view of an electron beam generator 101 according to the second embodiment.

The electron beam generator 101 includes the light-emitting device 1 described above and a photoelectric conversion layer 41. The photoelectric conversion layer 41 is provided on the substrate 21 so as to face the second surface 21B of the substrate 21 and the through-hole 21C in the first direction Z. In this embodiment, the photoelectric conversion layer 41 is in contact with the second surface 21B of the substrate 21. Further, the photoelectric conversion layer 41 blocks the opening of the through-hole 21C on the second surface 21B side.

The photoelectric conversion layer 41 absorbs the light L emitted by the light-emitting element 12 and emits photoelectrons. From the photoelectric conversion layer 41, a multi-electron beam e exits. As the material of the photoelectric conversion layer 41, for example, diamond, Cs—Sb alkali metal, Cs—GaAs, or Cs—GaN can be used.

According to this embodiment, since optical crosstalk in the light-emitting device 1 can be reduced, it is possible to prevent an unintended position from being irradiated with the electron beam e.

As shown in FIG. 5, the photoelectric conversion layer 41 may be located apart from the second surface 21B of the substrate 21 in the first direction Z. The separation distance between the photoelectric conversion layer 41 and the second surface 21B of the substrate 21 in the first direction Z is preferably 50 μm or less.

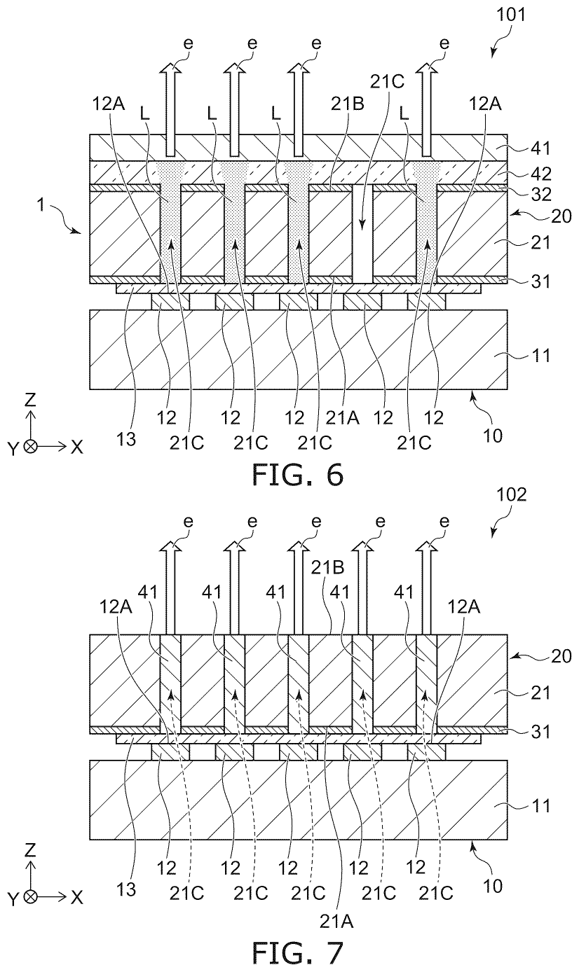

As shown in FIG. 6, the photoelectric conversion layer 41 may be supported on a transparent substrate 42. As the transparent substrate 42, for example, a sapphire substrate can be used. The thickness of the transparent substrate 42 is preferably 50 μm or less. The transparent substrate 42 is located between the second surface 21B of the substrate 21 and the photoelectric conversion layer 41 in the first direction Z, and between the through-hole 21C and the photoelectric conversion layer 41 in the first direction Z. In this case, it is preferable that a second light absorbing layer 32 be provided on the second surface 21B of the substrate 21. The transparent substrate 42 is in contact with the second light absorbing layer 32.

The second light absorbing layer 32 is absorptive of the light emitted by the light-emitting element 12. The reflectance of the second light absorbing layer 32 is preferably 10% or less, and the coefficient of absorption of the second light absorbing layer 32 is preferably 10 μm⁻¹ or more. The second light absorbing layer 32 can include, for example, at least one selected from the group consisting of an organic material, graphene, carbon nanotubes, and amorphous carbon.

With the second light absorbing layer 32, it is possible to prevent the light L exiting from the through-hole 21C from being laterally guided in the transparent substrate 42, and to reduce crosstalk of the light L entering the photoelectric conversion layer 41.

### Third Embodiment

FIG. 7 is a schematic cross-sectional view of an electron beam generator 102 according to a third embodiment.

In the electron beam generator 102 according to the third embodiment, the photoelectric conversion layer 41 is provided in the through-hole 21C in the substrate 21. Since the photoelectric conversion layer 41 is provided in the through-hole 21C, it is possible to reduce a loss of light as compared with the case where the photoelectric conversion layer 41 is disposed on the second surface 21B side of the substrate 21, thereby improving the photoelectric conversion efficiency while reducing optical crosstalk.

### Fourth Embodiment

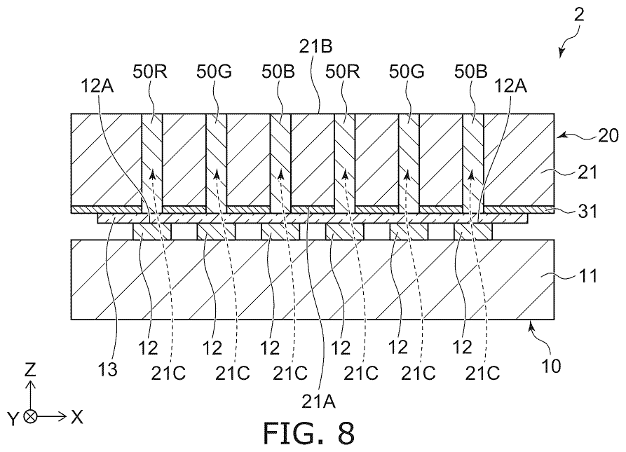

FIG. 8 is a schematic cross-sectional view of a light-emitting device 2 according to a fourth embodiment.

In the light-emitting device 2 according to the fourth embodiment, a wavelength conversion member is provided in the through-hole 21C. The wavelength conversion member is excited by the light emitted by the light-emitting element 12, and emits light having a wavelength different from that of the light emitted by the light-emitting element 12. As the wavelength conversion member, for example, a phosphor or a pigment can be used.

In the plurality of through-holes 21C, for example, three types of wavelength conversion members (a first wavelength conversion member 50R, a second wavelength conversion member 50G, and a third wavelength conversion member 50B) are provided. The first wavelength conversion member 50R includes a phosphor that is excited by the ultraviolet light emitted by the light-emitting element 12 and emits a red light. The second wavelength conversion member 50G includes a phosphor that is excited by the ultraviolet light emitted by the light-emitting element 12 and emits a green light. The third wavelength conversion member 50B includes a phosphor that is excited by the ultraviolet light emitted by the light-emitting element 12 and emits a blue light.

The light-emitting device 2 according to the fourth embodiment is applicable to, for example, a display. One unit including the first wavelength conversion member 50R, the second wavelength conversion member 50G, and the third wavelength conversion member 50B forms one pixel in the display. When the plurality of light-emitting elements 12 arranged at a fine pitch are used, it is possible to provide a fine and high-definition display.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A light-emitting device comprising:
a light-emitting element array including a wiring substrate and a plurality of light-emitting elements mounted on the wiring substrate; and
a hole member including a substrate and a plurality of through-holes formed in the substrate, the substrate including a first surface facing the light-emitting element array and a second surface located on a side opposite to the first surface,
the plurality of through-holes respectively facing light-emitting surfaces of the plurality of light-emitting elements.

2. The light-emitting device according to claim 1, wherein
the light-emitting elements emit ultraviolet light, and
the substrate is a silicon substrate.

3. The light-emitting device according to claim 1, further comprising:
a light absorbing layer provided on the first surface and/or the second surface of the substrate and absorptive of light emitted by the light-emitting elements.

4. The light-emitting device according to claim 3, wherein
the light-emitting elements emit ultraviolet light,
the substrate is a silicon substrate, and
the light absorbing layer includes at least one selected from the group consisting of an organic material, graphene, carbon nanotubes, and amorphous carbon.

5. The light-emitting device according to claim 3, wherein
a reflectance of the light absorbing layer is 10% or less, and a coefficient of absorption of the light absorbing layer is 10 μm⁻¹ or more.

6. The light-emitting device according to claim 1, wherein
a reflectance of inner walls of the through-holes with respect to light emitted by the light-emitting elements is 50% or more.

7. The light-emitting device according to claim 1, further comprising:
a wavelength conversion member provided in the through-holes.

8. A charged particle beam generator comprising:
the light-emitting device according to claim 1; and
a photoelectric conversion layer provided so as to face the second surface of the substrate and the through-holes.

9. A charged particle beam generator comprising:
the light-emitting device according to claim 1; and
a photoelectric conversion layer provided in the through-holes.
